(19) United States
(12) Patent Application Publication
(10) Pub. No.: US 2004/0239350 A1
(43) Pub. Date: Dec. 2, 2004

(54) Novel solution for low cost, speedy probe cards

(76) Inventors: Mohan R. Nagar, Milpitas, CA (US); Kishor Desai, Fremont, CA (US); Shirish Shah, San Ramon, CA (US)

Correspondence Address: LSI Logic Corporation, Legal Department-IP, MS D-106, 1621 Barber Lane, Milpitas, CA, 95035, US

(21) Appl. No.: 10/692,110

(22) Filed: Oct. 23, 2003

Related U.S. Application Data
(63) Continuation-in-part of application No. 10/448,987, filed on May 30, 2003, now abandoned.
(63) Continuation-in-part of application No. 10/620,057, filed on Jul. 15, 2003.

(51) Int. Cl. G01R 31/02

(52) U.S. Cl. 324/754

(57) ABSTRACT

Probe cards for measuring package interconnect impedance. A first probe card includes a package having solder balls on a first surface, and an electrically conductive material on a second surface. The electrically conductive surface is configured to electrically contact bumps on the substrate. The solder balls are mountable to a test head inter phase board of the tester. The probe card does not have any probe pins, and is configured to make electrical contact with bumps on the substrate without using probe pins. A second probe card includes a substrate with solder balls on one side and solder on pad (SOP) on the other side. Vertical probe pins contact the SOP and act as an interface between a tester and solder bumps on a wafer.

### RELATED APPLICATIONS (PRIORITY CLAIM)

This application is a continuation-in-part of U.S. patent application Ser. No. 10/620,057, filed Jul. 14, 2003 and U.S. patent application Ser. No. 10/448,987, filed May 30, 2003. Both of these applications are hereby incorporated herein by reference in their entirety.

### BACKGROUND

The present invention generally relates to methods and apparatuses for measuring package interconnect impedance, and more specifically relates to a method and apparatus for measuring the impedance of a substrate trace in a consistent manner for large sample sizes, multiple traces, in an automated fashion.

Presently, there is no widely available method and apparatus for monitoring impedance tolerance across different substrate families with various process/assembly variations. There is no widely available method and apparatus that can measure any trace on a package, can measure multiple traces at high speed, in an automated matter. There is no widely available method and apparatus which standardizes the impedance measurement technique and which can be implemented at necessary sites.

U.S. patent application Ser. Nos. 10/620,057 and 10/448,987 (incorporated herein by reference) disclose methods and apparatuses which can monitor impedance tolerance across different substrate families with various process/assembly variations, which can measure any trace on a package, and which can measure multiple traces at high speed, in an automated matter. The methods and apparatuses can standardize the impedance measurement technique and can be implemented at necessary sites.

U.S. patent application Ser. Nos. 10/620,057 and 10/448,987 disclose a method and apparatus wherein a test head from a tester is used to mount a probe card. A device under test (DUT)/load board is provided, and the DUT/load board has a socket which is configured to hold a substrate. Probe pins from the probe card make contact with bump pads on the substrate. The probe card is either fully populated to meet the bump pads on the substrate, and all except one pin are grounded. Signal wires from the DUT/load board are fed to the tester, and the tester is connected to a Digital Sampling Oscilloscope (DSO) with a fast rise time signal head. During testing, a signal is launched using the DSO into a coaxial cable which is connected to the probe card via the test head. The launched signal and the reflected signal are captured back by the DSO, and then fed into the tester via GPIB connections (i.e., a GPIB cable). Using this data, post processing software is used to obtain the interconnect impedance versus time for the device (i.e., package) under test. The method and apparatus can be used in connection with both Flip Chip and Wire bonded products.

U.S. patent application Ser. No. 10/620,057 discloses another embodiment, wherein the final test socket mounted on the load board is used. Specifically, the substrate with solder balls attached is dropped into the socket, and the DSO is connected to the tester head with a GPIB cable and to the DUT/load board with a coaxial cable. The DUT/load board, already attached to the tester head, can then be used to measure the impedance.

The present invention is directed to low cost, speedy probe cards for use in connection with wafer sort probing, such as in association with methods and apparatuses like those which are disclosed in U.S. patent application Ser. Nos. 10/620,057 and 10/448,987.

### OBJECTS AND SUMMARY

An object of an embodiment of the present invention is to provide a probe card used in wafer sort probing, where the probe card is low cost and speedy.

Another object of an embodiment of the present invention is to provide a probe card which does not include any probe pins.

Briefly, and in accordance with at least one of the foregoing objects, an embodiment of the present invention provides a probe card mountable to a tester for use in a system for measuring package interconnect impedance. The probe card includes a package having solder balls on a first surface thereof, and an electrically conductive material on a second surface thereof. The electrically conductive surface is configured to electrically contact bumps on the substrate. The solder balls are mountable to a test head inter phase board of the tester. The probe card does not have any probe pins, and is configured to make electrical contact with bumps on the substrate without using probe pins.

Another embodiment of the present invention provides a probe card which includes a substrate with solder balls on one side and solder on pad (SOP) on the other side. Vertical probe pins contact the SOP. The probe pins are connected to the substrate, are contactable with solder bumps on a wafer, and act as an interface between a tester and the solder bumps. The substrate is preferably ceramic, and the whole assembly is housed and mounted to a DUT board. The SOP, in cross-section, is built up longer (as with the probe pins, length can be varied and the material which is used can be any that is electrically conducting and suitable for the application). The SOP is preferably made tall by building on existing SOP and/or using a different alloy to build up the SOP. The solder balls on the one side of the substrate is connected to the DUT board. The process reduces the cost of additional hardware and saves time, such as connecting the vertical pins to SOP.

### BRIEF DESCRIPTION OF THE DRAWINGS

The organization and manner of the structure and operation of the invention, together with further objects and advantages thereof, may best be understood by reference to the following description, taken in connection with the accompanying drawing, wherein:

FIG. 1 is a diagram of a test apparatus for wafer sort probing, where the test apparatus includes a probe card;

FIG. 2 is a cross-sectional diagram of a probe card which is in accordance with an embodiment of the present invention, where the probe card can be used in association with the test apparatus shown in FIG. 1;

FIG. 3 is a flow chart of a method which is in accordance with an embodiment of the present invention;

FIG. 4 is a cross-sectional diagram of a probe card which is in accordance with another embodiment of the present invention; and

FIG. 5 is a flow chart of a method of making the probe card shown in FIG. 4.

### DESCRIPTION

While the invention may be susceptible to embodiment in different forms, there are shown in the drawings, and herein will be described in detail, specific embodiments with the understanding that the present disclosure is to be considered an exemplification of the principles of the invention, and is not intended to limit the invention to that as illustrated and described herein.

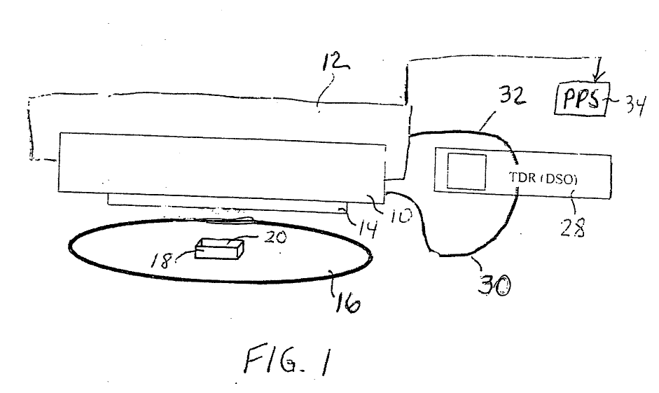

As shown in the FIG. 1, a tester head 10 of a tester 12 is used to mount a probe card 14. A device under test (DUT)/load board 16 is provided, and the DUT/load board 16 has a socket 18 which is configured to hold a substrate 20. The probe card 14 makes electrical contact with bump pads on the substrate 20. The tester 12 is connected to a Digital Sampling Oscilloscope (DSO) 28 with a fast rise time signal head. During testing, a signal is launched using the DSO into a coaxial cable 30 which then connects to the tester head 10. The launched signal and the reflected signal are captured back by the DSO 28, and then fed into the tester 12 via GPIB connections (i.e., a GPIB cable 32). Using this data, post processing software 34 is used to obtain the interconnect impedance versus time for the device (i.e., package) under test. The method and apparatus can be used in connection with both Flip Chip and Wire bonded products.

The tester head 10 lets the TDR signal out using the coaxial cable 30 and then allows the reflection from the DUT to get back to the TDR scope 28. The tester head 10 then uses the GPIB cable 32 connected to the DSO 28 to obtain the wave form and stores the data in a file.

Alternatively, a final test socket mounted on the load board 16 is used. Specifically, the substrate 20 is dropped into the socket, and the DSO 28 is connected to the tester 12 with a GPIB cable 32 and to the tester head 10 with a coaxial cable 30. The tester head 10 lets the TDR signal out using the coaxial cable 30 and then allows the reflection from the DUT to get back to the TDR scope 28. The tester head 10 then uses the GPIB cable 32 connected to the DSO 28 to obtain the waveform and stores the data in a file. Post processing software 34 is used to obtain the interconnect impedance versus time for the device (i.e., package) under test.

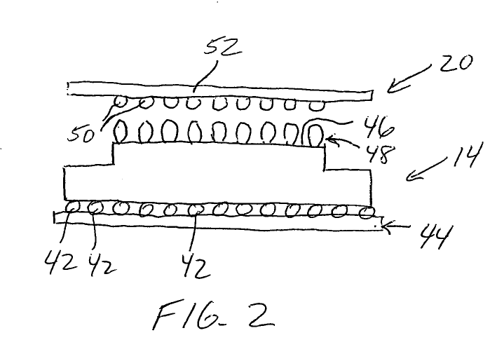

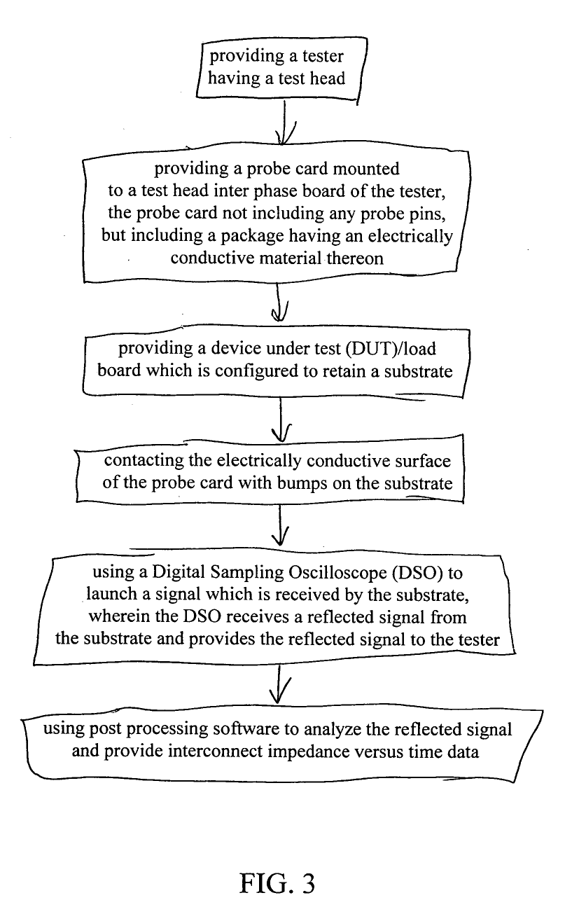

Regardless, preferably a probe card 14 in accordance with an embodiment of the present invention, as shown in FIG. 2, is used. As shown in FIG. 2, a package 40 with solder balls 42 thereon contactably engages a test head inter phase board 44, and on a pad [TALL] 46 of the package 40 is electrically conductive material 48. Specifically, probe material can be laid with a foundation of Copper on which a coating of solder can be plated. Regardless, the electrically conductive material 48 is configured to engage the substrate 20, specifically bumps 50 on a wafer 52. The probe card shown in FIG. 2 can be used to test new devices, or possibly for electrical verification. The probe card is simple and eliminates the cycle time needed to make expensive probe cards. It should be noted that while FIG. 2 illustrates the probe card on the bottom and the substrate on the top, the probe card can be on the top and the substrate on the bottom. FIG. 3 is a flow chart which illustrates a method of using such a probe card, and is self-explanatory.

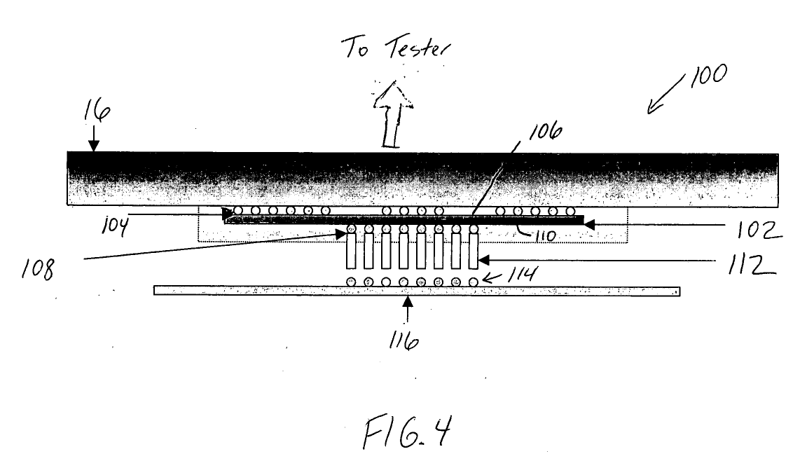

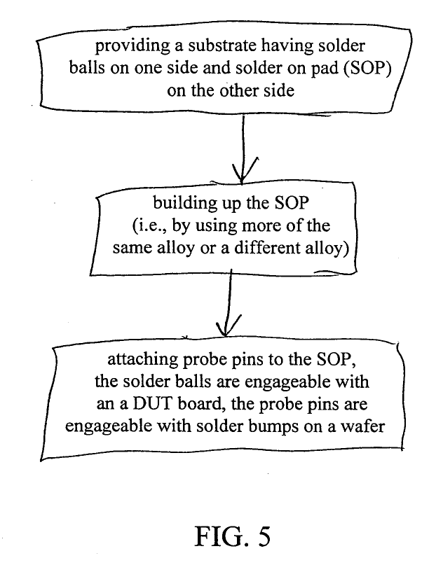

FIG. 4 illustrates a probe card 100 which is in accordance with another embodiment of the present invention. As shown, the probe card 100 includes a substrate 102, such as an organic substrate (i.e., ceramic), with solder balls 104 on one side 106 and solder on pad (SOP) 108 on the other side 110. Vertical probe pins 112 contact the SOP 108. The probe pins 112 are connected to the substrate 102 (via the SOP 108) and act as an interface between a tester (see FIG. 1) and solder bumps 114 on a wafer 116. The whole assembly is preferably housed and mounted to a DUT board 16 (see FIG. 1). The SOP, in cross-section, is built up longer (as with the probe pins, length can be varied and the material which is used can be any that is electrically conducting and suitable for the application). The SOP 108 is preferably made tall by building on existing SOP and/or using a different alloy to build up the SOP. The solder balls 104 on the one side 106 of the substrate 102 are connected to the DUT board 16. The process reduces the cost of additional hardware and saves time, such as connecting the vertical pins to SOP. FIG. 5 is a flow chart of a method of making the probe card shown in FIG. 4, and is self-explanatory.

While embodiments of the present invention are shown and described, it is envisioned that those skilled in the art may devise various modifications of the present invention without departing from the spirit and scope of the appended claims.

What is claimed is:

1. A probe card mountable to a device under test (DUT) board tester for use in a system for testing solder bumps on a wafer, the DUT being connected to a tester, said probe card comprising: a substrate having solder balls on one side and solder on pad (SOP) on the other side; probe pins in contact with the SOP, said probe pins being connected to the substrate via the SOP and being engageable with the solder bumps on the wafer, said probe pins acting as an interface between the tester and the solder bumps.

2. The probe card as recited in claim 1, wherein the substrate is organic.

3. The probe card as recited in claim 1, wherein the substrate is ceramic.

4. The probe card as recited in claim 1, wherein the SOP comprises a first alloy disposed on a second alloy, wherein the second alloy is different than the first alloy.

5. A method of making a probe card mountable to a device under test (DUT) board tester for use in a system for testing solder bumps on a wafer, the DUT being connected to a tester, said method comprising: providing a substrate having solder balls on one side and solder on pad (SOP) on the other side; and attaching probe pins to the SOP, wherein the probe pins are connected to the substrate via the SOP.

6. The method as recited in claim 5, further comprising building up the SOP before attaching the probe pins to the SOP.

7. The method as recited in claim 6, said SOP being formed of a first alloy, wherein the step of building up the SOP before attaching the probe pins to the SOP comprises adding more first alloy to the SOP.

8. The method as recited in claim 6, said SOP being formed of a first alloy, wherein the step of building up the SOP before attaching the probe pins to the SOP comprises adding a second alloy to the first alloy, said second alloy being different than said first alloy.

9. A probe card mountable to a tester for use in a system for measuring package interconnect impedance, the system including the tester, a device under test (DUT)/load board which is configured to retain a substrate, the DUT/load board being connected to the tester, the tester being connected to a Digital Sampling Oscilloscope (DSO) configured to receive a reflected signal from the substrate and provide the reflected signal to the tester, wherein the tester is configured to analyze the reflected signal and provide interconnect impedance versus time data, said probe card comprising: a package having solder balls on a first surface thereof, and a electrically conductive material on a second surface thereof, said electrically conductive surface configured to electrically contact bumps on the substrate.

10. The probe card as recited in claim 9, said solder balls mountable to a test head inter phase board of the tester.

11. The probe card as recited in claim 9, wherein the probe card does not have any probe pins.

12. The probe card as recited in claim 9, wherein the probe card is configured to make electrical contact with bumps on the substrate without using probe pins.

13. A method for measuring package interconnect impedance, said method comprising: providing a tester having a test head; providing a probe card mounted to the test head of the tester, said probe card including a package having solder balls on a first surface thereof mounted to the test head, and an electrically conductive material on a second surface of the package, said electrically conductive surface configured to electrically contact bumps on the substrate, providing a device under test (DUT)/load board which is configured to retain a substrate, said tester being connected to a Digital Sampling Oscilloscope (DSO); contacting said electrically conductive surface of said probe card with bumps on the substrate; using said DSO to launch a signal which is received by the substrate, wherein said DSO is configured to receive a reflected signal from the substrate and provide the reflected signal to the tester; and using post processing software to analyze the reflected signal and provide interconnect impedance versus time data.

14. The method as recited in claim 13, further comprising mounting the probe card to a test head inter phase board of the tester.

15. The method as recited in claim 13, further comprising engaging said probe card with the substrate without using any probe pins.
